(19) United States
(12) Patent Application Publication
(10) Pub. No.: US 2026/0269716 A1
(43) Pub. Date: Sep. 10, 2026

(54) DUAL-CHANNEL CURRENT-EQUALIZING FILTER CIRCUIT

(71) Applicant: Suzhou MetaBrain Intelligent Technology Co., Ltd., Suzhou, Jiangsu (CN)

(72) Inventors: Lingyan WANG, Suzhou, Jiangsu (CN); Deyang HUA, Suzhou, Jiangsu (CN); Dongyu ZHANG, Suzhou, Jiangsu (CN); Jianyu LI, Suzhou, Jiangsu (CN)

(21) Appl. No.: 18/876,285

(22) PCT Filed: Jun. 28, 2023
(86) PCT No.: PCT/CN2023/103132

§ 371 Date: Dec. 18, 2024

(30) Foreign Application Priority Data
Dec. 6, 2022 (CN) 202211553038.2

(51) Int. Cl. G06F 1/18; G06F 1/26; H01F 17/00; H01F 17/04; H02H 3/087

(52) U.S. Cl. CPC G06F 1/189; G06F 1/26; H01F 17/04; H02H 3/087; H01F 2017/0093

(57) ABSTRACT

The present application relates to the technical field of power supplies, and provides a dual-channel current-equalizing filter circuit. The circuit includes a first channel module, a second channel module, and magnetic modules connected thereto. Currents flowing through the first channel module and the second channel module generate magnetic fluxes under an action of the magnetic modules, whereby the currents flowing through the first channel module and the second channel module tend to be equalized. In addition, the circuit further has effects: preventing a fault of pulling down a bus voltage due to short circuit, suppressing a surge voltage, being high in design reliability, and preventing reverse plugging.

This application claims priority to Chinese Patent Application No. 202211553038.2, filed on Dec. 6, 2022 in China National Intellectual Property Administration, and entitled “DUAL-CHANNEL CURRENT-EQUALIZING FILTER CIRCUIT”, which is incorporated herein by reference in its entirety.

### FIELD

The present application relates to the technical field of power supplies, and in particular, to a dual-channel current-equalizing filter circuit.

### BACKGROUND

In recent years, with the rapid growth of high-performance computing applications such as artificial intelligence, machine learning, and big data mining, centralized computation and storage in data centers have been flourishing. To meet these growing demands, many large data centers for data computation, processing, and storage have been built, making data centers critical infrastructure for supporting normal operation of the modern society. A current situation of a current technology is as follows: At a server level, a power supply unit (PSU) reduces Alternating Current (AC) from 220 V to 12 V and supplies it to a server interface. Then, a BUCK (a buck converter) power supply on a mainboard reduces a voltage to different voltages such as 1.8 V or 1 V, thereby supplying power to a Central Processing Unit (CPU), an internal memory, and the like.

As demands for data processing increase, the power consumption of a CPU, a Graphics Processing Unit (GPU), and the like in a server has surged. Consequently, a power level required for supplying power to a power input port of the server has gradually increased by order of magnitude, posing numerous challenges for traditional power supplying methods for a high-voltage input side: 1. Multiplication of input power leads to multiplication of input current. Conduction loss of components such as an Electro Magnetic Compatibility (EMC) component at the interface is multiplied, resulting in severe heat generation. 2. Usually, a server power supply needs to be designed at a standard height 1U. Due to increases in both the input power and the current, it is difficult to select and design the relevant component such as the EMC component at the input port, resulting in a severe problem that a single component is ultra-high. 3. In a limited space, a large volume of a single component on an input side makes it difficult in arrangement of a Printed Circuit Board (PCB). 4. An input port connector and the EMC component have multiplied demands for current. As a result, there are no relevant shelf products available for selection, causing problems of a long product customization cycle and a high cost.

For this reason, a current server power supply often uses an Electro Magnetic Interference (EMI) passive filter which is widely applied to suppressing electromagnetic interference due to its simple structure, convenient design, and low cost. An EMI filter can effectively suppress conducted electromagnetic interference noise of a power converter. A suppression mechanism of the EMI filter is mainly to increase an impedance of a noise transmission channel by connecting filter inductors in series on line L and line N and to bypass electromagnetic interference noise by connecting filter capacitors in parallel, whereby a power supply product can meet relevant electromagnetic compatibility standards.

At present, server power supplies are being developed towards high voltage, high power, high power density, and low electromagnetic interference. This poses great challenges to the design of the EMI filter. As electromagnetic interference increases, a common method in engineering is to increase an inductance value of a filter inductor and a capacitance value of a filter capacitor, or increase the order of the filter, to meet an electromagnetic compatibility requirement. Meanwhile, an increase in power or an increase in input current will inevitably lead to an increase in a diameter of a flow channel of an element such as a filter inductor. This will inevitably increase a weight and volume of the filter. This is contrary to high power density. Moreover, since the server power supply needs to be designed with a limited height according to the standard height 1U, it is difficult to select the relevant components such as the EMC component at the input port due to the increases in the inductance, the power, and the current, causing severe problems that a single component is ultra-high and it is hard to arrange a board in a narrow space.

In terms of a filter circuit with a magnetic integrated structure, Lin Subin, Yu Xingwang, Chen Wei, and Zhang Liping from Fuzhou University have proposed a design method for a magnetic integrated structure of an EMI filter, with patent publication number CN114266213A. A design method for a magnetically integrated inductor structure is used to further reduce a volume of a filter on the premise that the filter circuit is favorable for ensuring a noise suppression effect. This method mainly integrates two differential mode inductors Ldm1 and Ldm2 at front and back of a rectifier bridge of an EMI filter onto a fully decoupled magnetic core to achieve a purpose of reducing a volume and weight of the entire filter circuit. This circuit has neither solved the problem that it is difficult to design filter-related elements in a narrow space when input power is high, nor applied magnetic integration to a current-equalizing function of the filter circuit.

For high energy consumption and high power density development demands of existing servers, with an increasing power demand for CPUs, GPUs, and the like, a power level required for power supplying gradually increases in order of magnitude, causing the problem that it is difficult to design and select components on an input side because power and current of the input side are multiplied. It is an urgent need for a solution a high-voltage and high-current input-side EMC filter circuit. The relevant technology proposes a filter circuit structure with two input channels, to reduce input current and power of each input channel. However, the EMC circuit with the two input channels also have some drawbacks. 1) There is a deviation between impedances of input wires of the two channels at a power input port, and board arrangement in a narrow space further increases the deviation between the impedances of the input wires. 2) The batch consistency of input filter EMC components is poor, and there are deviations in capacitance and inductance of the components. Especially for common mode chokes and differential mode inductors, a plus or minus deviation in inductance of a batch of wires is 20%. 3) Some components have negative temperature coefficients. A higher temperature indicates a lower impedance, which will further lead to higher shared power that indicates a higher temperature. 4) The components at the input port share different powers and generate different amounts of heat. Components through which high current flows generate heat, which severely affects the reliability of a power supply. 5) If a maximum current inequality is considered to be 20%, a design value of average current of two input ports needs to be increased by 20% simultaneously, which will lead to a difficulty in circuit design and component parameter selection. Therefore, it is urgent to implement parallel connection and current equalization between the two channels of the proposed filter circuit structure with the two input channels, to improve the consistency of the circuit and the reliability of the power supply, and effectively lower the design difficulty. Based on the above technical demands, the present application proposes a dual-channel current-equalizing filter circuit.

### SUMMARY

To solve one or more of the foregoing technical problems, technical solutions used in the present application are as follows.

A dual-channel current-equalizing filter circuit is provided. The circuit includes:
a first channel module, a second channel module, a first magnetic module, and a second magnetic module;
the first channel module includes: a first port of first channel, a second port of first channel, a third port of first channel, a fourth port of first channel, and a third common mode choke; the third common mode choke includes: a first port of third common mode choke, a second port of third common mode choke, a third port of third common mode choke, and a fourth port of third common mode choke; the first port of third common mode choke serves as the first port of first channel; the second port of third common mode choke serves as the third port of first channel; the third port of third common mode choke serves as the second port of first channel; the fourth port of third common mode choke serves as the fourth port of first channel;
the second channel module includes: a first port of second channel, a second port of second channel, a third port of second channel, a fourth port of second channel, and a fourth common mode choke; the fourth common mode choke includes: a first port of fourth common mode choke, a second port of fourth common mode choke, a third port of fourth common mode choke, and a fourth port of fourth common mode choke; the first port of fourth common mode choke serves as the first port of second channel; the second port of fourth common mode choke serves as the third port of second channel; the third port of fourth common mode choke serves as the second port of second channel; the fourth port of fourth common mode choke serves as the fourth port of second channel;
the first magnetic module includes: a first port of first magnetic module, a second port of first magnetic module, a third port of first magnetic module, a fourth port of first magnetic module, a fifth port of first magnetic module, a sixth port of first magnetic module, a seventh port of first magnetic module, and an eighth port of first magnetic module;
the second magnetic module includes: a first port of second magnetic module, a second port of second magnetic module, a third port of second magnetic module, and a fourth port of second magnetic module;
the first port of first channel is connected to a first positive input end; the second port of first channel is connected to a first negative input end; the first port of second channel is connected to a second positive input end; the second port of second channel is connected to the second negative input end;
the third port of first channel is electrically connected to the third port of first magnetic module; the fourth port of first channel is electrically connected to the first port of first magnetic module; the third port of second channel is electrically connected to the fifth port of first magnetic module; the fourth port of second channel is electrically connected to the seventh port of first magnetic module; the second port of first magnetic module serves as a negative output end of the dual-channel current-equalizing filter circuit after being electrically connected to the sixth port of second magnetic module; the fourth port of first magnetic module is electrically connected to the first port of second magnetic module; the eighth port of first magnetic module is electrically connected to the third port of second magnetic module; the second port of second magnetic module serves as a positive output end of the dual-channel current-equalizing filter circuit after being electrically connected to the fourth port of second magnetic module; and
the dual-channel current-equalizing filter circuit is configured to equalize currents flowing through the first channel module and the second channel module.

In an implementation of the present application, the first magnetic module includes: a first common mode choke and a second common mode choke; and the first common mode choke is magnetically integrated with the second common mode choke.

In an implementation of the present application, the first common mode choke includes: a first port of first common mode choke, a second port of first common mode choke, a third port of first common mode choke, and a fourth port of first common mode choke;
the second common mode choke includes: a first port of second common mode choke, a second port of second common mode choke, a third port of second common mode choke, and a fourth port of second common mode choke;
the first port of first common mode choke serves as the first port of first magnetic module; the second port of first common mode choke serves as the second port of first magnetic module; the third port of first common mode choke serves as the third port of first magnetic module; the fourth port of first common mode choke serves as the fourth port of first magnetic module; the first port of second common mode choke serves as the fifth port of first magnetic module; the second port of second common mode choke serves as the sixth port of first magnetic module; the third port of second common mode choke serves as the seventh port of first magnetic module; the fourth port of second common mode choke serves as the eighth port of first magnetic module; and
the first port of first common mode choke, the third port of first common mode choke, the second port of second common mode choke, and the fourth port of second common mode choke are in-phase ends.

In an implementation of the present application, the second magnetic module includes: a first differential mode inductor and a second differential mode inductor; and the first differential mode inductor is magnetically integrated with the second differential mode inductor.

In an implementation of the present application, the first differential mode inductor includes: a first port of first differential mode inductor and a second port of first differential mode inductor; the second differential mode inductor includes: a first port of second differential mode inductor and a second port of second differential mode inductor;
the first port of first differential mode inductor serves as the first port of second magnetic module; the second port of first differential mode inductor serves as the second port of second magnetic module; the first port of second differential mode inductor serves as the third port of second magnetic module; the second port of second differential mode inductor serves as the fourth port of second magnetic module; and
the second port of first differential mode inductor and the first port of second differential mode inductor are in-phase ends.

In an implementation of the present application, the circuit further includes a first capacitor; and the first capacitor is connected in parallel between the positive output end and the negative output end.

In an implementation of the present application, the first port of third common mode choke and the third port of third common mode choke are in-phase ends.

In an implementation of the present application, the first channel module further includes a first fusing module;
the first port of third common mode choke serves as the first port of first channel after being connected in series to the first fusing module; and
the first fusing module includes a first fuse protector.

In an implementation of the present application, the first fusing module further includes: a second fuse protector and a first resistor;
a branch formed by connecting the second fuse protector with the first resistor in series is connected in parallel to the first fuse protector; and
a sum of a resistance value of the second fuse protector and a resistance value of the first resistor is 20 to 50 times a resistance value of the first fuse protector.

In an implementation of the present application, the circuit further includes a second fusing module; the second fusing module includes: a third fuse protector and a first transient diode; and
a branch formed by connecting the third fuse protector with the first transient diode in series is connected in parallel between the first port of first channel and the second port of first channel.

In an implementation of the present application, the first transient diode is a bidirectional transient diode.

In an implementation of the present application, the circuit further includes a second transient diode;
a cathode of the second transient diode is electrically connected to the first port of third common mode choke; and an anode of the second transient diode is electrically connected to the second port of third common mode choke.

In an implementation of the present application, the circuit further includes a second capacitor; and the second capacitor is connected in parallel between the first port of third common mode choke and the third port of third common mode choke.

In an implementation of the present application, the circuit further includes a third capacitor; and the third capacitor is connected in parallel between the first port of first magnetic module and the third port of first magnetic module.

In an implementation of the present application, the second channel module further includes a third fusing module;
the first port of fourth common mode choke serves as the first port of second channel after being connected in series to the third fusing module; and
the third fusing module includes a fourth fuse protector.

In an implementation of the present application, the third fusing module further includes: a fifth fuse protector and a second resistor;
a branch formed by connecting the fifth fuse protector with the second resistor in series is connected in parallel to the fourth fuse protector; and
a sum of a resistance value of the fifth fuse protector and a resistance value of the second resistor is 20 to 50 times a resistance value of the fourth fuse protector.

In an implementation of the present application, the first port of fourth common mode choke and the third port of fourth common mode choke are in-phase ends.

In an implementation of the present application, the circuit further includes a fourth fusing module; the fourth fusing module includes: a sixth fuse protector and a third transient diode; and
a branch formed by connecting the sixth fuse protector with the third transient diode in series is connected in parallel between the first port of second channel and the second port of second channel.

In an implementation of the present application, the third transient diode is a bidirectional transient diode.

In an implementation of the present application, the circuit further includes a fourth transient diode; and
a cathode of the fourth transient diode is electrically connected to the first port of fourth common mode choke; and an anode of the fourth transient diode is electrically connected to the third port of fourth common mode choke.

In an implementation of the present application, the circuit further includes a fourth capacitor; and the fourth capacitor is connected in parallel between the first port of fourth common mode choke and the third port of fourth common mode choke.

In an implementation of the present application, the circuit further includes a fifth capacitor; and the fifth capacitor is connected in parallel between the fifth port of first magnetic module and the seventh port of first magnetic module.

The technical solutions provided by the embodiments of the present application bring the following beneficial effects:
1. The currents flowing through the two channels tend to be equal through the magnetically integrated common mode chokes and differential mode inductors.
2. A volume of the circuit is reduced by using the magnetically integrated common mode chokes and differential mode inductors, which is conductive to performing relevant server power supply design within a limited volume.
3. The fuse protectors are used to prevent a fault of pulling down a bus voltage caused by short circuit.
4. High reliability is provided for the circuit through a redundant design of the fuse protectors.
5. A surge voltage is suppressed through the transient diodes, and reverse plugging is prevented.

### BRIEF DESCRIPTION OF THE DRAWINGS

For clearer descriptions of the technical solutions according to the embodiments of the present application, the drawings required to be used in the description of the embodiments are briefly introduced below. It is obvious that the drawings in the description below are only some embodiments of the present application, and it is obvious for those skilled in the art that other drawings can be acquired according to the drawings without creative efforts.

FIG. 1 is a schematic diagram of modules of a dual-channel current-equalizing filter circuit provided by an embodiment of the present application;

FIG. 2 is a schematic diagram of a common mode choke provided by an embodiment of the present application;

FIG. 3 is a schematic diagram of a differential mode inductor provided by an embodiment of the present application;

FIG. 4 is a schematic diagram of winding current of a common mode choke provided by an embodiment of the present application;

FIG. 5 is a schematic diagram of winding current of a differential mode inductor provided by an embodiment of the present application; and

FIG. 6 is a schematic diagram of another dual-channel current-equalizing filter circuit provided by an embodiment of the present application.

### DETAILED DESCRIPTION

To make the objectives, technical solutions, and advantages of the present application clearer, the technical solutions in the implementations of the present application are clearly and completely described below with reference to the accompanying drawings in the implementations of the present application. Apparently, the described implementations are merely some rather than all the embodiments of the present application. All other embodiments obtained by a person of ordinary skill in the art based on the embodiments of the present application without making creative efforts shall fall within the protection scope of the present application.

Unless otherwise defined, technical or scientific terms used in the present application should have the ordinary meanings as understood by those of ordinary skill in the art to which the present application belongs. The terms “first”, “second”, and the like used in the present application do not indicate any order, quantity, or importance, but are only used to distinguish different components. Similarly, the term “one”, “a/an”, or the like does not indicate a quantity limit, but rather indicate at least one. The numbering in the accompanying drawings of this specification only indicates distinguishing between various functional components or modules, and does not represent logical relationships between the components or modules. The term “include”, “contain”, or another other similar term means that the elements or objects stated before them encompass the elements or objects and equivalents thereof listed after them, but do not exclude other elements or objects. The term such as “connect” or “connection” is not limited to physical or mechanical connection, but can include electrical connection, whether direct or indirect. The terms “upper”, “lower”, “left”, “right”, and the like are merely used to indicate relative positional relationships. After the absolute position of a described object changes, the relative positional relationship may also change accordingly.

The various embodiments of the present application will be described in detail below with reference to the accompanying drawings. It should be noted that in the accompanying drawings, the same reference numerals are assigned to components that have essentially the same or similar structures and functions, and repeated descriptions about them will be omitted.

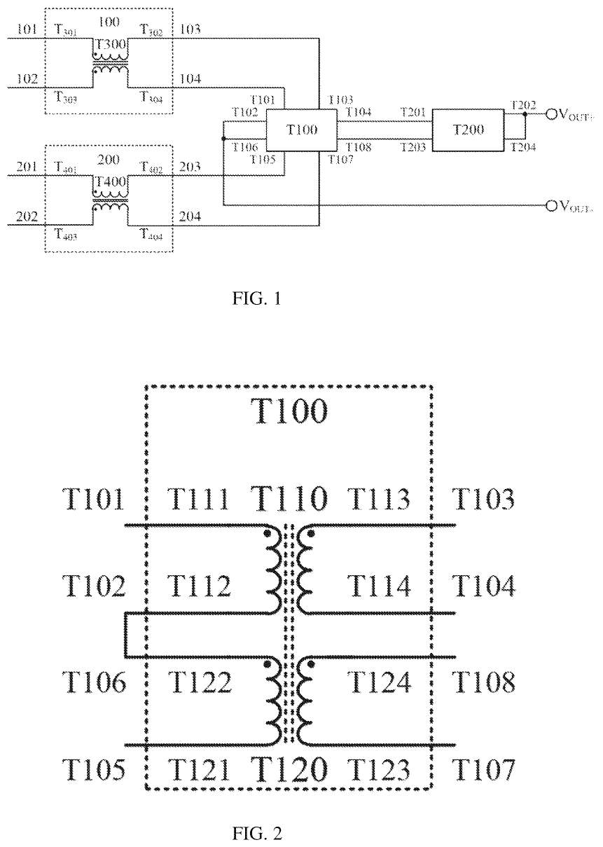

In an embodiment, as shown in FIG. 1, a dual-channel current-equalizing filter circuit is provided. The circuit includes:

A first channel module 100, a second channel module 200, a first magnetic module T100, and a second magnetic module T200 are included.

The first channel module 100 includes: a first port 101 of first channel, a second port 102 of first channel, a third port 103 of first channel, a fourth port 104 of first channel, and a third common mode choke T300. The third common mode choke T300 includes: a first port T301 of third common mode choke, a second port T302 of third common mode choke, a third port T303 of third common mode choke, and a fourth port T304 of third common mode choke. The first port T301 of third common mode choke serves as the first port 101 of first channel; the second port T302 of third common mode choke serves as the third port 103 of first channel; the third port T303 of third common mode choke serves as the second port 102 of first channel; and the fourth port T304 of third common mode choke serves as the fourth port 104 of first channel.

The second channel module 200 includes: a first port 201 of second channel, a second port 202 of second channel, a third port 203 of second channel, a fourth port 204 of second channel, and a fourth common mode choke T400. The fourth common mode choke T400 includes: a first port T401 of fourth common mode choke, a second port T402 of fourth common mode choke, a third port T403 of fourth common mode choke, and a fourth port T404 of fourth common mode choke. The first port T401 of fourth common mode choke serves as the first port 201 of second channel; the second port T402 of fourth common mode choke serves as the third port 203 of second channel; the third port T403 of fourth common mode choke serves as the second port 202 of second channel; and the fourth port T404 of fourth common mode choke serves as the fourth port 204 of second channel.

The first port 101 of first channel and the second port 102 of first channel are connected in parallel with the first port 201 of second channel and the second port 202 of second channel. When the above circuit works, the parallel-connected power supply ends can come from the same bus, or different buses can be used to supply power.

The first magnetic module T100 includes: a first port T101 of first magnetic module, a second port T102 of first magnetic module, a third port T103 of first magnetic module, a fourth port T104 of first magnetic module, a fifth port T105 of first magnetic module, a sixth port T106 of first magnetic module, a seventh port T107 of first magnetic module, and an eighth port T108 of first magnetic module.

The second magnetic module T200 includes: a first port T201 of second magnetic module, a second port T202 of second magnetic module, a third port T203 of second magnetic module, and a fourth port T204 of second magnetic module.

The first port 101 of first channel is connected to a first positive input end; the second port 102 of first channel is connected to a first negative input end; the first port 201 of second channel is connected to a second positive input end; and the second port 202 of second channel is connected to a second negative input end.

The third port 103 of first channel is electrically connected to the third port T103 of first magnetic module; the fourth port 104 of first channel is electrically connected to the first port T101 of first magnetic module; the third port 203 of second channel is electrically connected to the fifth port T105 of first magnetic module; the fourth port 204 of second channel is electrically connected to the seventh port T107 of first magnetic module; the second port T102 of first magnetic module serves as a negative output end of the dual-channel current-equalizing filter circuit after being electrically connected to the sixth port T206 of second magnetic module; the fourth port T104 of first magnetic module is electrically connected to the first port T201 of second magnetic module; the eighth port T108 of first magnetic module is electrically connected to the third port T203 of second magnetic module; the second port T202 of second magnetic module serves as a positive output end of the dual-channel current-equalizing filter circuit after being electrically connected to the fourth port T204 of second magnetic module.

The dual-channel current-equalizing filter circuit is configured to equalize currents flowing through the first channel module 100 and the second channel module 200.

As shown in FIG. 2, the first magnetic module T100 includes: a first common mode choke T110 and a second common mode choke T120. The first common mode choke T110 is magnetically integrated with the second common mode choke T120.

The first common mode choke T110 includes: a first port T111 of first common mode choke, a second port T112 of first common mode choke, a third port T113 of first common mode choke, and a fourth port T114 of first common mode choke.

The second common mode choke T120 includes: a first port T121 of second common mode choke, a second port T122 of second common mode choke, a third port T123 of second common mode choke, and a fourth port T124 of second common mode choke.

The first port T111 of first common mode choke serves as the first port T101 of first magnetic module; the second port T112 of first common mode choke serves as the second port T102 of first magnetic module; the third port T113 of first common mode choke serves as the third port T103 of first magnetic module; the fourth port T114 of first common mode choke serves as the fourth port T104 of first magnetic module; the first port T121 of second common mode choke serves as the fifth port T105 of first magnetic module; the second port T122 of second common mode choke serves as the sixth port T106 of first magnetic module; the third port T123 of second common mode choke serves as the seventh port T107 of first magnetic module; and the fourth port T124 of second common mode choke serves as the eighth port T108 of first magnetic module.

The first port T111 of first common mode choke, the third port T113 of first common mode choke, the second port T122 of second common mode choke, and the fourth port T124 of second common mode choke are in-phase ends. The second port T112 of first common mode choke, the fourth port T114 of first common mode choke, the first port T121 of second common mode choke, and the third port T123 of second common mode choke are out-of-phase ends.

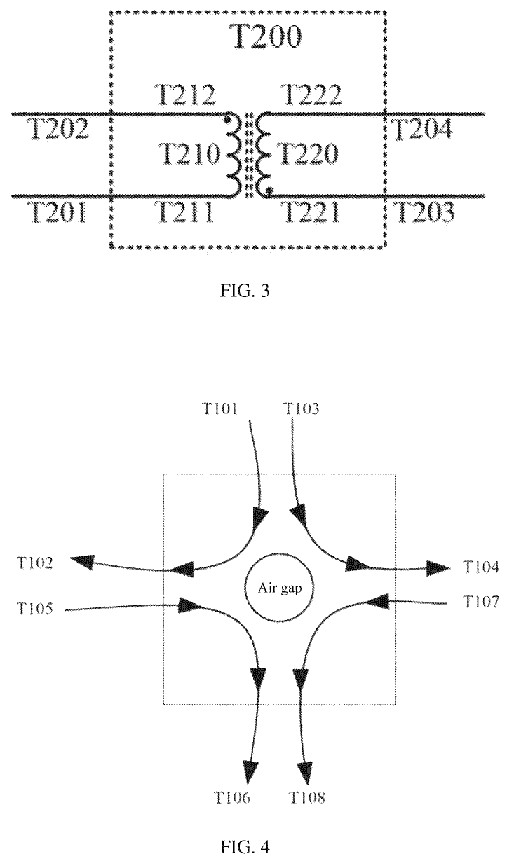

As shown in FIG. 3, the second magnetic module T200 includes: a first port T201 of second magnetic module, a second port T202 of second magnetic module, a third port T203 of second magnetic module, and a fourth port T204 of second magnetic module. During inductor winding, each group of coils starts to be wound from pins at the in-phase ends. One group is wound clockwise, and another group is wound counterclockwise. The coils are taken up from pins at the out-of-phase ends.

The second magnetic module T200 includes: a first differential mode inductor T210 and a second differential mode inductor T220. The first differential mode inductor T210 is magnetically integrated with the second differential mode inductor T220.

The first differential mode inductor T210 includes: a first port T211 of first differential mode inductor and a second port T212 of first differential mode inductor. The second differential mode inductor T220 includes: a first port T221 of second differential mode inductor and a second port T222 of second differential mode inductor.

The first port T211 of first differential mode inductor serves as the first port T201 of second magnetic module; the second port T212 of first differential mode inductor serves as the second port T202 of second magnetic module; the first port T221 of second differential mode inductor serves as the third port T203 of second magnetic module; and the second port T222 of second differential mode inductor serves as the fourth port T204 of second magnetic module.

The second port T212 of first differential mode inductor and the first port T221 of second differential mode inductor are in-phase ends.

A group of coils is provided between the first port T111 of first common mode choke and the second port T122 of second common mode choke. A group of coils is provided between the third port T113 of first common mode choke and fourth port T114 of first common mode choke. A group of coils is provided between the first port T121 of second common mode choke and the second port T122 of second common mode choke. A group of coils is provided between the third port T123 of second common mode choke and the fourth port T124 of second common mode choke. During inductor winding, each group of coils starts to be wound from the pins at the in-phase ends. This group is wound clockwise. The coils are taken up from the pins at the out-of-phase ends. Current flows in from the in-phase ends of the magnetically integrated common mode chokes and flows out from the out-of-phase ends of the magnetically integrated common mode chokes.

When current on positive and negative wires in the first channel module 100 flows from the corresponding in-phase ends of the first common mode choke T110, and magnetic fluxes generated by the currents flowing through the positive and negative wires enhance each other to suppress common mode interference. When current on positive and negative wires in the second channel module 200 flows from the corresponding out-of-phase ends of the second common mode choke T120, and magnetic fluxes generated by the currents flowing through the positive and negative wires enhance each other to suppress common mode interference.

The first magnetic module T100 is an inductor designed by performing magnetic integration on the first common mode choke T110 and the second common mode choke T120.

In an ideal state, the currents flowing through the first channel module 100 and the second channel module 200 are completely equal, and magnetic flux characteristics generated by the equal currents are completely equal. If the magnetic fluxes are in the same direction, they are multiplied. If the magnetic fluxes are in opposite directions, they are canceled out by each other. However, in practical applications, due to an inconsistency of component parameters and an inconsistency of wiring and routing, the currents in the first channel and the second channel are not completely the same, but have a deviation. As shown in FIG. 4, the second port T102 of first magnetic module and the fifth port T105 of first magnetic module are adjacently integrated and wound under a magnetic core, but currents on the corresponding coils are in opposite direction and generate opposite magnetic fluxes. When the currents of the first channel module and the second channel module are equal, the magnetic fluxes are completely canceled out.

If the magnetic flux generated by the first channel module is not completely canceled out by the magnetic flux generated by the second channel module, a coupling voltage is generated between the fifth port T105 of first magnetic module and the sixth port T106 of first magnetic module, which causes an increase in the current of the second channel module. Since total current of the first channel module and the second channel module is constant, the increase in the current of the second channel module is conducive to promoting the consistency in the currents of the first channel module and the second channel module and achieving an effect of current equalization.

There is an air gap in a center region of the first magnetic module T100, which achieves a high magnetic field coupling effect in adjacent regions and a low magnetic field coupling effect between diagonal regions of a magnetic material, to solve the uncertainty of complex magnetic field coupling under a plurality of groups of coils sharing the same magnetic material. By providing the air gap, a magnetic field coupling superposition effect is locked between adjacent coils to achieve the provided magnetically integrated common mode choke structure.

The second magnetic module T200 is an inductor designed by performing magnetic integration on two differential mode inductors. The first port T201 of second magnetic module and the second port T202 of second magnetic module form one group of differential mode inductor. The third port T203 of second magnetic module and the fourth port T204 of second magnetic module form the other group of differential mode inductor. The second port T202 of second magnetic module and the third port T203 of second magnetic module are in-phase ends. The first port T201 of second magnetic module and the fourth port T204 of second magnetic module are out-of-phase ends.

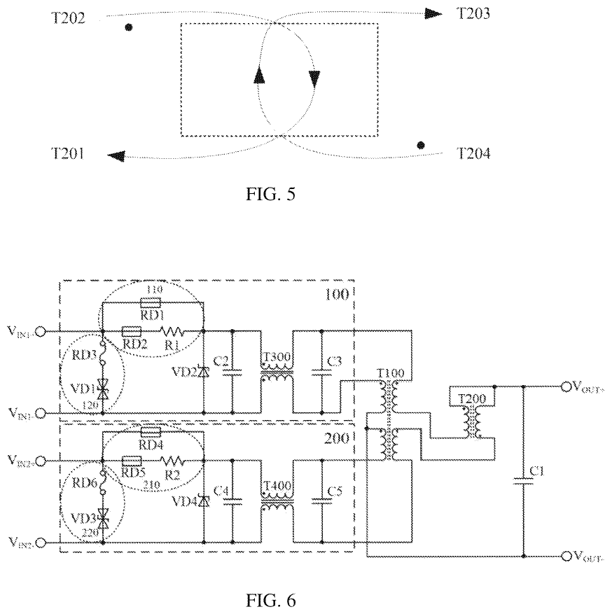

As shown in FIG. 5, the coils of both the first port T201 of second magnetic module and the second port T202 of second magnetic module are adjacently wound with the coils of both the third port T203 of second magnetic module and the fourth port T204 of second magnetic module under the same magnetic material. Current flows in from the in-phase ends and flows out from the out-of-phase ends. Since the winding directions are opposite, the generated magnetic fluxes have opposite directions. If the currents of the two groups of coils are completely equal, the magnetic fluxes generated are completely equal in magnitude and have opposite directions, completely canceling out, so that the magnetic fluxes can be completely canceled out. If the current of the first channel module is greater than that of the second channel module, the coil between the first port T201 of second magnetic module and the second port T202 of second magnetic module will couple and superimpose a voltage on the coil between the third port T203 of second magnetic module and the fourth port T204 of second magnetic module. This voltage is in the same direction as an input voltage. The voltage causes an increase in the current of the second channel module. Since the total current of the first channel module and the second channel module is constant, it ultimately promotes a consistency in the currents flowing through the first channel module and the second channel module. If the current of the first channel module is less than that of the second channel module, it can also be inferred that this circuit also has a promoting effect on the consistency of the total current of the first channel module and the second channel module.

A volume of the circuit is reduced by using the magnetically integrated common mode chokes and the magnetically integrated differential mode inductors. This is conductive to performing relevant server power supply design within a limited volume.

In another embodiment, the circuit further includes a first capacitor C1. The first capacitor is connected in parallel between the positive output end and the negative output end to energy storage filtering and circuit decoupling.

The first port T301 of third common mode choke and the third port T303 of third common mode choke are in-phase ends.

In another embodiment, the first channel module 100 further includes a first fusing module 110, as shown in FIG. 6.

The first port T301 of third common mode choke serves as the first port 101 of first channel after being connected in series to the first fusing module 110.

The first fusing module 110 includes a first fuse protector RD1.

Preferably, the first fusing module 110 further includes: a second fuse protector RD2 and a first resistor R1.

A branch formed by connecting the second fuse protector RD2 with the first resistor R1 in series is connected in parallel to the first fuse protector RD1.

A sum of a resistance value of the second fuse protector RD2 and a resistance value of the first resistor R1 is 20 to 50 times a resistance value of the first fuse protector RD1.

The second fuse protector RD2 and the first resistor R1 are connected in series to achieve redundant backup of the first fuse protector RD1. The redundant backup of the fuse protector can effectively improve the reliability of the circuit, which effectively avoids the problems of inability of effective and quick fusing due to a fault caused by a large design value and accidental fusing caused by a small design value. There is the first resistor R1 in the channel of the second fuse protector RD2, during normal working, the current flows through the first fuse protector RD1.

In another embodiment, the circuit further includes a second fusing module 120. The second fusing module 120 includes: a third fuse protector RD3 and a first transient diode VD1.

A branch formed by connecting the third fuse protector RD3 with the first transient diode VD1 in series is connected in parallel between the first port 101 of first channel and the second port 102 of first channel.

The third fuse protector RD3 and the first transient diode VD1 are connected in series with each other and are placed at a position, closest to an input port, on a power bus, which can more directly suppress a surge voltage at an input. Meanwhile, the third fuse protector RD3 can effectively prevent a severe fault situation of pulling down a bus voltage due to a short circuit fault of the first transient diode VD1.

Preferably, the first transient diode VD1 is a bidirectional transient diode that can suppress a bidirectional surge voltage between a positive end and a negative end of the input port.

The first fuse protector RD1 is arranged at a rear end of the first transient diode VD1. so that it does not consider a parameter risk of fusing the first fuse protector RD1 due to instantaneous surge absorption current of the first transient diode VD1. This helps the design and selection of the first fuse protector RD1 to deal with instantaneous fusing under a fault condition, and improves the design reliability.

In another embodiment, the circuit further includes a second transient diode VD2.

A cathode of the second transient diode VD2 is electrically connected to the first port T301 of third common mode choke; and an anode of the second transient diode VD2 is electrically connected to the second port T302 of third common mode choke.

The second transient diode VD2 can be replaced with a high-current diode. The second transient diode VD2 can further suppress the surge voltage and prevent damage to a surge voltage of a component at a rear input bus port, and can effectively prevent reverse connection. When the positive end and the negative end of the input port are connected reversely, the second transient diode VD2 is in positive conduction to clamp the input voltage to form a current channel. This effectively prevents an inverse voltage from impacting the component at the rear input port.

In another embodiment, the circuit further includes a second capacitor C2. The second capacitor C2 is connected in parallel between the first port T301 of third common mode choke and the third port T303 of third common mode choke. The second capacitor C2 is used for energy storage filtering and circuit decoupling.

In another embodiment, the circuit further includes a third capacitor C3. The third capacitor C3 is connected in parallel between the first port T101 of first magnetic module and the third port T103 of first magnetic module to achieve energy storage filtering and circuit decoupling.

In another embodiment, the second channel module 200 further includes a third fusing module 210.

The first port T401 of fourth common mode choke serves as the first port 201 of second channel after being connected in series to the third fusing module 210.

The third fusing module 210 includes a fourth fuse protector RD4.

Preferably, the third fusing module 210 further includes: a fifth fuse protector RD5 and a second resistor R2.

A branch formed by connecting the fifth fuse protector RD5 with the second resistor R2 in series is connected in parallel to the fourth fuse protector RD4.

A sum of a resistance value of the fifth fuse protector RD5 and a resistance value of the second resistor R2 is 20 to 50 times a resistance value of the fourth fuse protector RD4.

The first port T401 of fourth common mode choke and the third port T403 of fourth common mode choke are in-phase ends.

In another embodiment, the circuit further includes a fourth fusing module 220. The fourth fusing module 220 includes: a sixth fuse protector RD6 and a third transient diode VD3.

A branch formed by connecting the sixth fuse protector RD6 with the third transient diode VD3 in series is connected in parallel between the first port 201 of second channel and the second port 202 of second channel. The sixth fuse protector RD6 and the third transient diode VD3 are connected in series with each other and are placed at a position, closest to an input port, on a power bus, which can more directly suppress a surge voltage at an input. Meanwhile, the sixth fuse protector RD6 can effectively prevent a severe fault situation of pulling down a bus voltage due to a short circuit fault of the third transient diode VD3.

Preferably, the third transient diode VD3 is a bidirectional transient diode that can suppress a bidirectional surge voltage between a positive end and a negative end of the input port.

The fourth fuse protector RD4 is arranged at a rear end of the first transient diode VD3. so that it does not consider a parameter risk of fusing the fourth fuse protector RD4 due to instantaneous surge absorption current of the third transient diode VD3. This helps the design and selection of the fourth fuse protector RD4 to deal with instantaneous fusing under a fault condition, and improves the design reliability.

In another embodiment, the circuit further includes a fourth transient diode VD4.

A cathode of the fourth transient diode VD4 is electrically connected to the first port T401 of fourth common mode choke; and an anode of the fourth transient diode VD4 is electrically connected to the third port T403 of fourth common mode choke.

The fourth transient diode VD4 can be replaced with a high-current diode. The fourth transient diode VD4 can further suppress the surge voltage and prevent damage to a surge voltage of a component at a rear input bus port, and can effectively prevent reverse connection. When the positive end and the negative end of the input port are connected reversely, the fourth transient diode VD4 is in positive conduction to clamp the input voltage to form a current channel. This effectively prevents an inverse voltage from impacting the component at the rear input port.

In another embodiment, the circuit further includes a fourth capacitor C4. The fourth capacitor C4 is connected in parallel between the first port T401 of fourth common mode choke and the third port T403 of fourth common mode choke to achieve energy storage filtering and circuit decoupling.

In another embodiment, the circuit further includes a fifth capacitor C5. The fifth capacitor C5 is connected in parallel between the fifth port T105 of first magnetic module and the seventh port T107 of first magnetic module.

By implementing the technical solutions provided by the embodiments of the present application, the input current and bearing power of a core power component are reduced under high power. Based on an existing mature component system with high voltage and high current, the problem of difficulty in design and selection of components on an input side due to a phased increase in a power level of a power supply. The following problem is solved: An increase in a deviation between impedances of two layout wires due to an inconsistency of parameters of components between two input filter channels and a narrow power supply space causes currents of the two input channels to be unequal. As a result, components need to be selected according to a peak current of the unequal currents, and heat generated inside the dual-channel circuit is not uniform. By using a working effect that coupled magnetic fields are canceled each other out or superimposed with each other, an inductor magnetic-integration and coupling design structure of a dual-channel input circuit is proposed to achieve current equalization, power equalization, and heat equalization during dual-channel parallel inputting. Focusing on characteristics that the common mode chokes and the differential mode inductors have inconsistent inductances, usually with a maximum inductance deviation of 10% to 20%, a severe problem that a single channel bears the entire power at a moment of peak power. This structure achieves that if directions of common mode currents generated in the same common mode choke are the same, magnetic fluxes are superimposed to resist common mode interference. Directions of currents flowing through the coils of different input channels of the magnetically integrated common mode chokes are opposite, so that instantaneously generated magnetic fluxes are canceled each other out. When the currents between the two input channels are completely equal, the magnetic fluxes are completely canceled out, and the magnetically integrated common mode chokes do not work. However, when the input current of one channel is high, a large magnetic flux is generated, and the uncanceled magnetic flux will instantaneously couple and superimpose a voltage component on the coil with low current, which is close to the same magnetic core. As the voltage increases, the current increases. Due to a constant total input current value, the current in the channel with high current decreases, to achieve a working characteristic of promoting current equalization between the two input channels. Through the magnetically integrated common mode choke with the air gap in the center region, a high magnetic field coupling effect in adjacent regions and a low magnetic field coupling effect between diagonal regions of a magnetic material are achieved, to solve the uncertainty of complex magnetic field coupling under multiple coils sharing the same magnetic material. By providing the air gap, a magnetic field coupling superposition effect is locked between adjacent coils to achieve that the provided magnetically integrated common mode choke structure has a large engineering application value, which promotes current equalization between the two input channels, achieves winding of two inductors under a single magnetic core, reduces the volume and the weight, and effectively increases a power density indicator of the power supply. Meanwhile, due to the existence of the magnetic cancellation characteristic, an inductance core has low loss and low heat generation, which is beneficial for increasing an efficiency indicator. The design structure of placing the diodes at front sections of the fuse protectors of the input channels solves the problem of difficulty in design and selection of the fuse protectors on the input channels. Usually, to prevent accidental fusing of the fuse protectors during lightning surge, it is very difficult to ensure rapid fusing of the fuse protectors under an abnormal working condition, which often leads to a large design value and achieves the characteristics of suppressing input and preventing reverse connection. This structure is simple and does not generate additional conduction voltage drop loss in a main power channel.

All the optional technical solutions mentioned above can be combined in any way to form the optional embodiments of the present application, and will not be elaborated here.

### Embodiment I

A first channel module 100, a second channel module 200, a first magnetic module T100, and a second magnetic module T200 are included.

The first channel module 100 includes: a first port 101 of first channel, a second port 102 of first channel, a third port 103 of first channel, a fourth port 104 of first channel, and a third common mode choke T300. The third common mode choke T300 includes: a first port T301 of third common mode choke, a second port T302 of third common mode choke, a third port T303 of third common mode choke, and a fourth port T304 of third common mode choke. The first port T301 of third common mode choke serves as the first port 101 of first channel; the second port T302 of third common mode choke serves as the third port 103 of first channel; the third port T303 of third common mode choke serves as the second port 102 of first channel; and the fourth port T304 of third common mode choke serves as the fourth port 104 of first channel.

The second channel module 200 includes: a first port 201 of second channel, a second port 202 of second channel, a third port 203 of second channel, a fourth port 204 of second channel, and a fourth common mode choke T400. The fourth common mode choke T400 includes: a first port T401 of fourth common mode choke, a second port T402 of fourth common mode choke, a third port T403 of fourth common mode choke, and a fourth port T404 of fourth common mode choke. The first port T401 of fourth common mode choke serves as the first port 201 of second channel; the second port T402 of fourth common mode choke serves as the third port 202 of second channel; the third port T403 of fourth common mode choke serves as the second port 202 of second channel; and the fourth port T404 of fourth common mode choke serves as the fourth port 204 of second channel.

The first port 101 of first channel and the second port 102 of first channel are connected in parallel with the first port 201 of second channel and the second port 202 of second channel. When the above circuit works, the parallel-connected power supply ends can come from the same bus, or different buses can be used to supply power.

The first magnetic module T100 includes: a first port T101 of first magnetic module, a second port T102 of first magnetic module, a third port T103 of first magnetic module, a fourth port T104 of first magnetic module, a fifth port T105 of first magnetic module, a sixth port T106 of first magnetic module, a seventh port T107 of first magnetic module, and an eighth port T108 of first magnetic module.

The second magnetic module T200 includes: a first port T201 of second magnetic module, a second port T202 of second magnetic module, a third port T203 of second magnetic module, and a fourth port T204 of second magnetic module.

The first port 101 of first channel is connected to a first positive input end; the second port 102 of first channel is connected to a first negative input end; the first port 201 of second channel is connected to a second positive input end; and the second port 202 of second channel is connected to a second negative input end.

The third port 103 of first channel is electrically connected to the third port T103 of first magnetic module; the fourth port 104 of first channel is electrically connected to the first port T101 of first magnetic module; the third port 203 of second channel is electrically connected to the fifth port T105 of first magnetic module; the fourth port 204 of second channel is electrically connected to the seventh port T107 of first magnetic module; the second port T102 of first magnetic module serves as a negative output end of the dual-channel current-equalizing filter circuit after being electrically connected to the sixth port T206 of second magnetic module; the fourth port T104 of first magnetic module is electrically connected to the first port T201 of second magnetic module; the eighth port T108 of first magnetic module is electrically connected to the third port T203 of second magnetic module; the second port T202 of second magnetic module serves as a positive output end of the dual-channel current-equalizing filter circuit after being electrically connected to the fourth port T204 of second magnetic module.

The dual-channel current-equalizing filter circuit is configured to equalize currents flowing through the first channel module 100 and the second channel module 200.

### Embodiment II

As shown in FIG. 6, a first channel module 100, a second channel module 200, a first magnetic module T100, and a second magnetic module T200 are included.

The first channel module 100 includes: a first port 101 of first channel, a second port 102 of first channel, a third port 103 of first channel, a fourth port 104 of first channel, and a third common mode choke T300. The third common mode choke T300 includes: a first port T301 of third common mode choke, a second port T302 of third common mode choke, a third port T303 of third common mode choke, and a fourth port T304 of third common mode choke. The first port T301 of third common mode choke serves as the first port 101 of first channel; the second port T302 of third common mode choke serves as the third port 103 of first channel; the third port T303 of third common mode choke serves as the second port 102 of first channel; and the fourth port T304 of third common mode choke serves as the fourth port 104 of first channel.

The second channel module 200 includes: a first port 201 of second channel, a second port 202 of second channel, a third port 203 of second channel, a fourth port 204 of second channel, and a fourth common mode choke T400. The fourth common mode choke T400 includes: a first port T401 of fourth common mode choke, a second port T402 of fourth common mode choke, a third port T403 of fourth common mode choke, and a fourth port T404 of fourth common mode choke. The first port T401 of fourth common mode choke serves as the first port 201 of second channel; the second port T402 of fourth common mode choke serves as the third port 202 of second channel; the third port T403 of fourth common mode choke serves as the second port 202 of second channel; and the fourth port T404 of fourth common mode choke serves as the fourth port 204 of second channel.

The first port 101 of first channel and the second port 102 of first channel are connected in parallel with the first port 201 of second channel and the second port 202 of second channel. When the above circuit works, the parallel-connected power supply ends can come from the same bus, or different buses can be used to supply power.

The first magnetic module T100 includes: a first port T101 of first magnetic module, a second port T102 of first magnetic module, a third port T103 of first magnetic module, a fourth port T104 of first magnetic module, a fifth port T105 of first magnetic module, a sixth port T106 of first magnetic module, a seventh port T107 of first magnetic module, and an eighth port T108 of first magnetic module.

The second magnetic module T200 includes: a first port T201 of second magnetic module, a second port T202 of second magnetic module, a third port T203 of second magnetic module, and a fourth port T204 of second magnetic module.

The first port 101 of first channel is connected to a first positive input end; the second port 102 of first channel is connected to a first negative input end; the first port 201 of second channel is connected to a second positive input end; and the second port 202 of second channel is connected to a second negative input end.

The third port 103 of first channel is electrically connected to the third port T103 of first magnetic module; the fourth port 104 of first channel is electrically connected to the first port T101 of first magnetic module; the third port 203 of second channel is electrically connected to the fifth port T105 of first magnetic module; the fourth port 204 of second channel is electrically connected to the seventh port T107 of first magnetic module; the second port T102 of first magnetic module serves as a negative output end of the dual-channel current-equalizing filter circuit after being electrically connected to the sixth port T106 of first magnetic module; the fourth port T104 of first magnetic module is electrically connected to the first port T201 of second magnetic module; the eighth port T108 of first magnetic module is electrically connected to the third port T203 of second magnetic module; the second port T202 of second magnetic module serves as a positive output end of the dual-channel current-equalizing filter circuit after being electrically connected to the fourth port T204 of second magnetic module.

The dual-channel current-equalizing filter circuit is configured to equalize currents flowing through the first channel module 100 and the second channel module 200.

The first magnetic module T100 includes: a first common mode choke T110 and a second common mode choke T120. The first common mode choke T110 is magnetically integrated with the second common mode choke T120.

The first common mode choke T110 includes: a first port T111 of first common mode choke, a second port T112 of first common mode choke, a third port T113 of first common mode choke, and a fourth port T114 of first common mode choke.

The second common mode choke T120 includes: a first port T121 of second common mode choke, a second port T122 of second common mode choke, a third port T123 of second common mode choke, and a fourth port T124 of second common mode choke.

The first port T111 of first common mode choke serves as the first port T101 of first magnetic module; the second port T112 of first common mode choke serves as the second port T102 of first magnetic module; the third port T113 of first common mode choke serves as the third port T103 of first magnetic module; the fourth port T114 of first common mode choke serves as the fourth port T104 of first magnetic module; the first port T121 of second common mode choke serves as the fifth port T105 of first magnetic module; the second port T122 of second common mode choke serves as the sixth port T106 of first magnetic module; the third port T123 of second common mode choke serves as the seventh port T107 of first magnetic module; and the fourth port T124 of second common mode choke serves as the eighth port T108 of first magnetic module.

The first port T111 of first common mode choke, the third port T113 of first common mode choke, the second port T122 of second common mode choke, and the fourth port T124 of second common mode choke are in-phase ends.

The second magnetic module T200 includes: a first differential mode inductor T210 and a second differential mode inductor T220. The first differential mode inductor T210 is magnetically integrated with the second differential mode inductor T220.

The first differential mode inductor T210 includes: a first port T211 of first differential mode inductor and a second port T212 of first differential mode inductor. The second differential mode inductor T220 includes: a first port T221 of second differential mode inductor and a second port T222 of second differential mode inductor.

The first port T211 of first differential mode inductor serves as the first port T201 of second magnetic module; the second port T212 of first differential mode inductor serves as the second port T202 of second magnetic module; the first port T221 of second differential mode inductor serves as the third port T203 of second magnetic module; and the second port T222 of second differential mode inductor serves as the fourth port T204 of second magnetic module.

The second port T212 of first differential mode inductor and the first port T221 of second differential mode inductor are in-phase ends.

The circuit further includes a first capacitor C1. The first capacitor is connected in parallel between the positive output end and the negative output end.

The first port T301 of third common mode choke and the third port T303 of third common mode choke are in-phase ends.

The first channel module 100 further includes a first fusing module 110.

The first port T301 of third common mode choke serves as the first port 101 of first channel after being connected in series to the first fusing module 110.

The first fusing module 110 includes a first fuse protector RD1.

The first fusing module 110 further includes: a second fuse protector RD2 and a first resistor R1.

A branch formed by connecting the second fuse protector RD2 with the first resistor R1 in series is connected in parallel to the first fuse protector RD1.

A sum of a resistance value of the second fuse protector RD2 and a resistance value of the first resistor R1 is 20 to 50 times a resistance value of the first fuse protector RD1.

The circuit further includes a second fusing module 120. The second fusing module 120 includes: a third fuse protector RD3 and a first transient diode VD1. A branch formed by connecting the third fuse protector RD3 with the first transient diode VD1 in series is connected in parallel between the first port 101 of first channel and the second port 102 of first channel.

The first transient diode VD1 is a bidirectional transient diode.

The circuit further includes a second transient diode VD2.

A cathode of the second transient diode VD2 is electrically connected to the first port T301 of third common mode choke; and an anode of the second transient diode VD2 is electrically connected to the third port T303 of third common mode choke.

The circuit further includes a second capacitor C2. The second capacitor C2 is connected in parallel between the first port T301 of third common mode choke and the third port T303 of third common mode choke.

The circuit further includes a third capacitor C3. The third capacitor C3 is connected in parallel between the first port T101 of first magnetic module and the third port T103 of first magnetic module.

The second channel module 200 further includes a third fusing module 210.

The first port T401 of fourth common mode choke serves as the first port 201 of second channel after being connected in series to the third fusing module 210.

The third fusing module 210 includes a fourth fuse protector RD4.

The third fusing module 210 further includes: a fifth fuse protector RD5 and a second resistor R2.

A branch formed by connecting the fifth fuse protector RD5 with the second resistor R2 in series is connected in parallel to the fourth fuse protector RD4.

A sum of a resistance value of the fifth fuse protector RD5 and a resistance value of the second resistor R2 is 20 to 50 times a resistance value of the fourth fuse protector RD4.

The first port T401 of fourth common mode choke and the third port T403 of fourth common mode choke are in-phase ends.

The circuit further includes a fourth fusing module 220. The fourth fusing module 220 includes: a sixth fuse protector RD6 and a third transient diode VD3. A branch formed by connecting the sixth fuse protector RD6 with the third transient diode VD3 in series is connected in parallel between the first port 201 of second channel and the second port 202 of second channel.

The third transient diode VD3 is a bidirectional transient diode.

The circuit further includes a fourth transient diode VD4.

A cathode of the fourth transient diode VD4 is electrically connected to the first port T401 of fourth common mode choke; and an anode of the fourth transient diode VD4 is electrically connected to the third port T403 of fourth common mode choke.

The circuit further includes a fourth capacitor C4. The fourth capacitor C4 is connected in parallel between the first port T401 of fourth common mode choke and the third port T403 of fourth common mode choke.

The circuit further includes a fifth capacitor C5. The fifth capacitor C5 is connected in parallel between the fifth port T105 of first magnetic module and the seventh port T107 of first magnetic module.

Particularly, according to the embodiments of the present application, the process described in the reference flowchart above can be implemented as a computer software program. For example, the embodiments of the present application include a computer program product, including a computer program carried on a computer-readable medium, and the computer program includes program codes used for performing the methods shown in the flowcharts. In such an embodiment, the computer program may be downloaded and installed from a network through a communication apparatus, or installed from a memory, or installed from a Read-Only Memory (ROM). When the computer program is executed by an external processor, the above-mentioned functions defined in the method disclosed by the embodiments of the present application are executed.

It should be noted that the computer-readable medium of the embodiments of the present application can be a computer-readable signal medium, a computer-readable storage medium, or any combination of the computer-readable signal medium and the computer-readable storage medium. The computer-readable storage medium can be, for example, but not limited to, electric, magnetic, optical, electromagnetic, infrared, or semiconductor systems, apparatuses, or devices, or any combination of the above. More specific examples of the computer-readable storage medium may include, but are not limited to: an electrical connection with one or more wires, a portable computer disk, a hard disk drive, a Random Access Memory (RAM), a ROM, an Erasable Programmable Read Only Memory (EPROM) or flash memory, an optical fiber, a Compact Disc Read-Only Memory (CD-ROM), an optical storage device, a magnetic storage device, or any suitable combination of the above. In the embodiments of the present application, the computer-readable storage medium may be any tangible medium that contains or stores a program, and the program can be used by or in combination with an instruction execution system, apparatus, or device. In the embodiments of the present application, computer-readable signal media may include data signals propagated in a baseband or as part of a carrier wave, which carries computer-readable program codes. The propagated data signals can be in various forms, including but not limited to: electromagnetic signals, optical signals, or any suitable combination of the above. The computer-readable signal medium may also be any computer-readable medium other than a computer-readable storage medium. The computer-readable signal medium can send, propagate, or transmit programs for use by or in combination with an instruction execution system, apparatus, or device. The program codes contained in the computer-readable medium can be transmitted using any suitable medium, including but not limited to: a wire, an optical cable, a Radio Frequency (RF), and the like, or any suitable combination of the above.

The computer-readable medium may be included in the above server or exist alone and is not assembled into the server.

Computer program codes for performing the operations of the embodiments of the present application may be written in one or more programming languages or a combination thereof. The above programming languages include an object-oriented programming language (such as Java, Smalltalk, and C++), and conventional procedural programming languages (such as “C” language or similar programming languages). The program codes may be executed entirely on a user computer, partly on a user computer, as a stand-alone software package, partly on a user computer and partly on a remote computer, or entirely on a remote computer or a server. In a case where a remote computer is involved, the remote computer can be connected to a user computer through any kind of networks, including a LAN or a WAN, or can be connected to an external computer (for example, through an Internet using an Internet service provider).

The various embodiments in this specification are all described progressively, and the same similar parts between the various embodiments can be referred to each other. Each embodiment focuses on differences from other embodiments. Particularly, the system or system embodiment is basically similar to the method embodiment, and therefore is described briefly. For related parts, refer to some of the descriptions in the method embodiment. The system and the system embodiment described above are only schematic. The units described as separate parts may or may not be physically separate, and parts displayed as units may or may not be physical units, may be located in one position, or may be distributed on a plurality of network units. Some or all of the modules are selected according to actual needs to achieve the objective of the solution of this embodiment. Those of ordinary skill in the art can understand and implement the present application without creative work.

The technical solutions provided by the present application are described in detail above. Specific examples are used herein to illustrate the principles and implementations of the present application. The descriptions of the above embodiments are only used to help understand the method of the present application and its core idea; and at the same time, those of ordinary skill in the art will make changes to all the specific implementations and application scopes according to the idea of the present application. In conclusion, the content of this specification shall not be understood as a limitation on the present application.

The foregoing descriptions are merely preferred embodiments of the present application, but are not intended to limit present application. Any modification, equivalent replacement, or improvement made within the spirit and principle of present application shall fall within the protection scope of the present application.

What is claimed is:

1. A dual-channel current-equalizing filter circuit, comprising:
a first channel module, a second channel module, a first magnetic module, and a second magnetic module;
wherein the first channel module comprises: a first port of first channel, a second port of first channel, a third port of first channel, a fourth port of first channel, and a third common mode choke; the third common mode choke comprises: a first port of third common mode choke, a second port of third common mode choke, a third port of third common mode choke, and a fourth port of third common mode choke; the first port of third common mode choke serves as the first port of first channel; the second port of third common mode choke serves as the third port of first channel; the third port of third common mode choke serves as the second port of first channel; the fourth port of third common mode choke serves as the fourth port of first channel;
the second channel module comprises: a first port of second channel, a second port of second channel, a third port of second channel, a fourth port of second channel, and a fourth common mode choke; the fourth common mode choke comprises: a first port of fourth common mode choke, a second port of fourth common mode choke, a third port of fourth common mode choke, and a fourth port of fourth common mode choke; the first port of fourth common mode choke serves as the first port of second channel; the second port of fourth common mode choke serves as the third port of second channel; the third port of fourth common mode choke serves as the second port of second channel; the fourth port of fourth common mode choke serves as the fourth port of second channel;
the first magnetic module comprises: a first port of first magnetic module, a second port of first magnetic module, a third port of first magnetic module, a fourth port of first magnetic module, a fifth port of first magnetic module, a sixth port of first magnetic module, a seventh port of first magnetic module, and an eighth port of first magnetic module;
the second magnetic module comprises: a first port of second magnetic module, a second port of second magnetic module, a third port of second magnetic module, and a fourth port of second magnetic module;
the first port of first channel is connected to a first positive input end; the second port of first channel is connected to a first negative input end; the first port of second channel is connected to a second positive input end; the second port of second channel is connected to a second negative input end;
the third port of first channel is electrically connected to the third port of first magnetic module; the fourth port of first channel is electrically connected to the first port of first magnetic module; the third port of second channel is electrically connected to the fifth port of first magnetic module; the fourth port of second channel is electrically connected to the seventh port of first magnetic module; the second port of first magnetic module serves as a negative output end of the dual-channel current-equalizing filter circuit after being electrically connected to the sixth port of first magnetic module; the fourth port of first magnetic module is electrically connected to the first port of second magnetic module; the eighth port of first magnetic module is electrically connected to the third port of second magnetic module; the second port of second magnetic module serves as a positive output end of the dual-channel current-equalizing filter circuit after being electrically connected to the fourth port of second magnetic module; and
the dual-channel current-equalizing filter circuit is configured to equalize currents flowing through the first channel module and the second channel module.

2. The dual-channel current-equalizing filter circuit according to claim 1, wherein the first magnetic module comprises: a first common mode choke and a second common mode choke; and the first common mode choke is magnetically integrated with the second common mode choke.

3. The dual-channel current-equalizing filter circuit according to claim 2, wherein the first common mode choke comprises: a first port of first common mode choke, a second port of first common mode choke, a third port of first common mode choke, and a fourth port of first common mode choke;
the second common mode choke comprises: a first port of second common mode choke, a second port of second common mode choke, a third port of second common mode choke, and a fourth port of second common mode choke; the first port of first common mode choke serves as the first port of first magnetic module; the second port of first common mode choke serves as the second port of first magnetic module; the third port of first common mode choke serves as the third port of first magnetic module; the fourth port of first common mode choke serves as the fourth port of first magnetic module; the first port of second common mode choke serves as the fifth port of first magnetic module; the second port of second common mode choke serves as the sixth port of first magnetic module; the third port of second common mode choke serves as the seventh port of first magnetic module; the fourth port of second common mode choke serves as the eighth port of first magnetic module; and the first port of first common mode choke, the third port of first common mode choke, the second port of second common mode choke, and the fourth port of second common mode choke are in-phase ends.

4. The dual-channel current-equalizing filter circuit according to claim 1, wherein the second magnetic module comprises: a first differential mode inductor and a second differential mode inductor; and the first differential mode inductor is magnetically integrated with the second differential mode inductor.

5. The dual-channel current-equalizing filter circuit according to claim 4, wherein the first differential mode inductor comprises: a first port of first differential mode inductor and a second port of first differential mode inductor; the second differential mode inductor comprises: a first port of second differential mode inductor and a second port of second differential mode inductor;
the first port of first differential mode inductor serves as the first port of second magnetic module; the second port of first differential mode inductor serves as the second port of second magnetic module; the first port of second differential mode inductor serves as the third port of second magnetic module; the second port of second differential mode inductor serves as the fourth port of second magnetic module; and
the second port of first differential mode inductor and the first port of second differential mode inductor are in-phase ends.

6. (canceled)

7. The dual-channel current-equalizing filter circuit according to claim 1, wherein the first port of third common mode choke and the third port of third common mode choke are in-phase ends.

8. The dual-channel current-equalizing filter circuit according to claim 1, wherein the first channel module further comprises a first fusing module;
the first port of third common mode choke serves as the first port of first channel after being connected in series to the first fusing module; and
the first fusing module comprises a first fuse protector.

9. The dual-channel current-equalizing filter circuit according to claim 8, wherein the first fusing module further comprises: a second fuse protector and a first resistor;
a branch formed by connecting the second fuse protector with the first resistor in series is connected in parallel to the first fuse protector; and
a sum of a resistance value of the second fuse protector and a resistance value of the first resistor is 20 to 50 times a resistance value of the first fuse protector.

10. The dual-channel current-equalizing filter circuit according to claim 1, wherein the dual-channel current-equalizing filter circuit further comprises a second fusing module; the second fusing module comprises: a third fuse protector and a first transient diode; and
a branch formed by connecting the third fuse protector with the first transient diode in series is connected in parallel between the first port of first channel and the second port of first channel.

11. The dual-channel current-equalizing filter circuit according to claim 1, wherein the dual-channel current-equalizing filter circuit further comprises a second transient diode;
a cathode of the second transient diode is electrically connected to the first port of third common mode choke; and an anode of the second transient diode is electrically connected to the third port of third common mode choke.

12-13. (canceled)

14. The dual-channel current-equalizing filter circuit according to claim 1, wherein the second channel module further comprises a third fusing module;
the first port of fourth common mode choke serves as the first port of second channel after being connected in series to the third fusing module; and
the third fusing module comprises a fourth fuse protector.

15. The dual-channel current-equalizing filter circuit according to claim 14, wherein the third fusing module further comprises: a fifth fuse protector and a second resistor;
a branch formed by connecting the fifth fuse protector with the second resistor in series is connected in parallel to the fourth fuse protector; and
a sum of a resistance value of the fifth fuse protector and a resistance value of the second resistor is 20 to 50 times a resistance value of the fourth fuse protector.

16. The dual-channel current-equalizing filter circuit according to claim 1, wherein the first port of fourth common mode choke and the third port of fourth common mode choke are in-phase ends.

17. The dual-channel current-equalizing filter circuit according to claim 1, wherein the dual-channel current-equalizing filter circuit further comprises a fourth fusing module; the fourth fusing module comprises: a sixth fuse protector and a third transient diode; and
a branch formed by connecting the sixth fuse protector with the third transient diode in series is connected in parallel between the first port of second channel and the second port of second channel.

18. The dual-channel current-equalizing filter circuit according to claim 1, wherein the dual-channel current-equalizing filter circuit further comprises a fourth transient diode; and
a cathode of the fourth transient diode is electrically connected to the first port of fourth common mode choke; and an anode of the fourth transient diode is electrically connected to the third port of fourth common mode choke.

19-20. (canceled)

21. A dual-channel current-equalizing filter circuit, comprising:
a first channel module, a second channel module, a first magnetic module, and a second magnetic module;
a first port of first channel of the first channel module is connected to a first positive input end; a second port of first channel of the first channel module is connected to a first negative input end; a first port of second channel of the second channel module is connected to a second positive input end; a second port of second channel of the second channel module is connected to a second negative input end;
a third port of first channel of the first channel module is electrically connected to a third port of first magnetic module; a fourth port of first channel of the first channel module is electrically connected to a first port of first magnetic module; a third port of second channel of the second channel module is electrically connected to a fifth port of first magnetic module; a fourth port of second channel of the second channel module is electrically connected to a seventh port of first magnetic module; a second port of first magnetic module serves as a negative output end of the dual-channel current-equalizing filter circuit after being electrically connected to a sixth port of first magnetic module; a fourth port of first magnetic module is electrically connected to a first port of second magnetic module; a eighth port of first magnetic module is electrically connected to a third port of second magnetic module; a second port of second magnetic module serves as a positive output end of the dual-channel current-equalizing filter circuit after being electrically connected to a fourth port of second magnetic module;
wherein the first magnetic module comprises: a first common mode choke and a second common mode choke; and the first common mode choke is magnetically integrated with the second common mode choke;
wherein the second magnetic module comprises: a first differential mode inductor and a second differential mode inductor; and the first differential mode inductor is magnetically integrated with the second differential mode inductor.

22. The dual-channel current-equalizing filter circuit according to claim 21, wherein the first channel module comprises a third common mode choke, the third common mode choke comprises: a first port of third common mode choke, a second port of third common mode choke, a third port of third common mode choke, and a fourth port of third common mode choke.

23. The dual-channel current-equalizing filter circuit according to claim 21, wherein the second channel module comprises a fourth common mode choke, the fourth common mode choke comprises: a first port of fourth common mode choke, a second port of fourth common mode choke, a third port of fourth common mode choke, and a fourth port of fourth common mode choke; the first port of fourth common mode choke serves as the first port of second channel; the second port of fourth common mode choke serves as the third port of second channel; the third port of fourth common mode choke serves as the second port of second channel; the fourth port of fourth common mode choke serves as the fourth port of second channel.

24. The dual-channel current-equalizing filter circuit according to claim 21, wherein the dual-channel current-equalizing filter circuit is configured to equalize currents flowing through the first channel module and the second channel module.

25. The dual-channel current-equalizing filter circuit according to claim 21, wherein the first common mode choke comprises: a first port of first common mode choke, a second port of first common mode choke, a third port of first common mode choke, and a fourth port of first common mode choke;
the second common mode choke comprises: a first port of second common mode choke, a second port of second common mode choke, a third port of second common mode choke, and a fourth port of second common mode choke; the first port of first common mode choke serves as the first port of first magnetic module; the second port of first common mode choke serves as the second port of first magnetic module; the third port of first common mode choke serves as the third port of first magnetic module; the fourth port of first common mode choke serves as the fourth port of first magnetic module; the first port of second common mode choke serves as the fifth port of first magnetic module; the second port of second common mode choke serves as a sixth port of first magnetic module; the third port of second common mode choke serves as the seventh port of first magnetic module; the fourth port of second common mode choke serves as the eighth port of first magnetic module; and the first port of first common mode choke, the third port of first common mode choke, the second port of second common mode choke, and the fourth port of second common mode choke are in-phase ends.
